(19) United States
(12) Patent Application Publication
(10) Pub. No.: US 2025/0118356 A1
(43) Pub. Date: Apr. 10, 2025

(54) APPARATUS INCLUDING CLOCK INPUT BUFFER

(71) Applicant: MICRON TECHNOLOGY, INC., Boise, ID (US)

(72) Inventors: Yasuhiro Takai, Sagamihara (JP); Shuichi Tsukada, Sagamihara (JP)

(73) Assignee: MICRON TECHNOLOGY, INC., Boise, ID (US)

(21) Appl. No.: 18/751,840

(22) Filed: Jun. 24, 2024

Related U.S. Application Data
(60) Provisional application No. 63/588,602, filed on Oct. 6, 2023.

(51) Int. Cl. G11C 11/4093; G11C 11/4076

(52) U.S. Cl. CPC G11C 11/4093; G11C 11/4076

(57) ABSTRACT

Embodiments of the disclosure provide an apparatus comprising: first and second input transistors of a first type and first and second load transistors of a second type coupled in series, respectively; at least one resistor coupled to gate nodes of the load transistors; and first and second capacitive devices. Gate nodes of the first and second input transistors are coupled to first and second inputs, respectively. The first input transistor and the first load transistor are coupled to a first output. The second input transistor and the second load transistor are coupled to a second output. The gate nodes of the first and second load transistors are coupled to a bias voltage through the resistor. The first and second capacitive devices are coupled to the first and second inputs and to the gate nodes of the first and second load transistors, respectively.

### CROSS REFERENCE TO RELATED APPLICATION(S)

This application claims priority to U.S. Provisional Application No. 63/588,602, filed Oct. 6, 2023. The aforementioned application is incorporated herein by reference, in its entirety, for any purpose.

### BACKGROUND

A clock input buffer is typically used to provide inputs to a variety of circuits. In one instance, in connection with a memory device, such as a dynamic random access memory (DRAM), a clock input buffer may receive an external clock signal and output an internal clock signal as a reference clock signal to, for example, latch input data.

There is a demand for a clock input buffer that can properly operate at a higher frequency without increasing current consumption.

### BRIEF DESCRIPTION OF THE DRAWINGS

FIG. 1 is a block diagram of an example semiconductor system according to an embodiment of the disclosure.

FIG. 2 is a circuit diagram of an example clock input buffer.

FIGS. 3A and 3B are circuit diagrams of example clock input buffers according to an embodiment of the disclosure.

FIGS. 4A and 4B illustrate example waveforms at a lower operating frequency and at a higher operating frequency, respectively, according to an embodiment of the disclosure.

FIG. 5 is a circuit diagram of an example bias voltage generator according to an embodiment of the disclosure.

FIG. 6 is a circuit diagram of an example clock input buffer according to an embodiment of the disclosure.

FIGS. 7A and 7B are circuit diagrams of example clock input buffers according to an embodiment of the disclosure.

FIGS. 8A and 8B are circuit diagrams of example clock input buffers according to an embodiment of the disclosure.

FIG. 9 depicts a schematic configuration of an example semiconductor system according to an embodiment of the disclosure.

### DETAILED DESCRIPTION

Various example embodiments of the disclosure will be described below in detail with reference to the accompanying drawings. The following detailed descriptions refer to the accompanying drawings that show, by way of illustration, specific aspects in which embodiments of the disclosure may be practiced. These embodiments are described in sufficient detail to enable those skilled in the art to practice the disclosure. Other embodiments may be utilized, and structure, logical and electrical changes may be made without departing from the scope of the disclosure. The various embodiments disclosed herein are not necessary mutually exclusive, as some disclosed embodiments can be combined with one or more other disclosed embodiments to form new embodiments.

In the descriptions, common or related elements and elements that are substantially the same are denoted with the same signs, and the descriptions thereof may be reduced or omitted. In the drawings, some of the same signs may be omitted for the same or substantially the same elements for case of illustration. In the drawings, the dimensions and dimensional ratios of each unit do not necessarily match the actual dimensions and dimensional ratios in the embodiments.

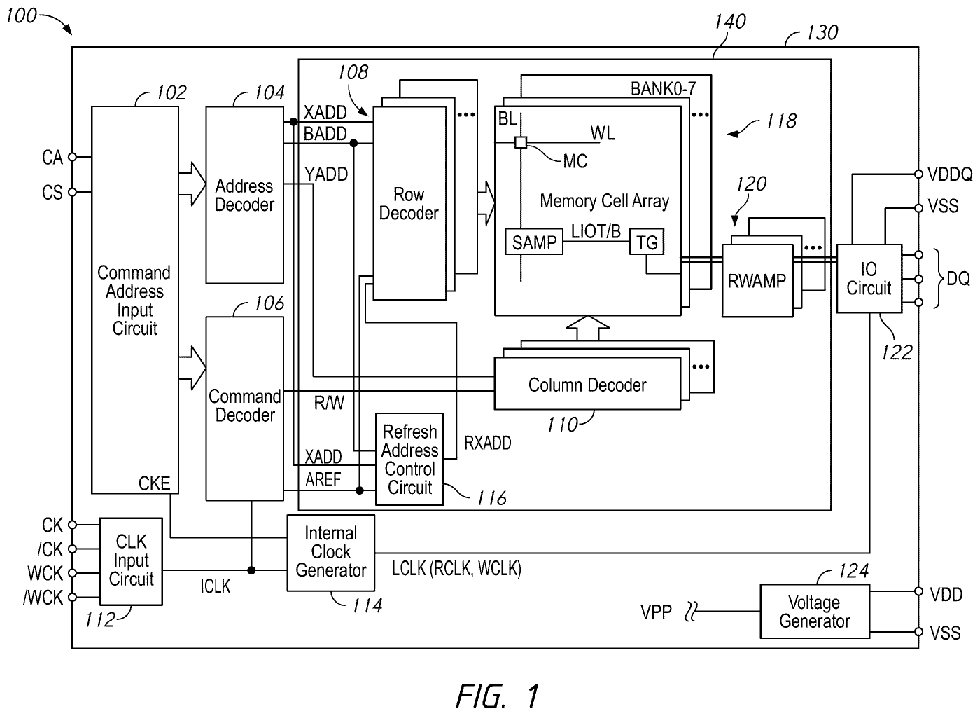

FIG. 1 is a block diagram of an example semiconductor device 100 according to an embodiment of the disclosure. The semiconductor device 100 may be a semiconductor memory device, such as a dynamic random access memory (DRAM) device. In some embodiments of the disclosure, the semiconductor device 100 may be included in a semiconductor memory device. The DRAM device may include an interface die and a plurality of core dice which are stacked on the interface die. In some embodiments, the DRAM device may be a High Bandwidth Memory (HBM) or a Hybrid Memory Cube (HMC). In some embodiments, the DRAM device may be a double data rate (DDR) DRAM. The DDR DRAM may be a low power DDR (LPDDR) DRAM.

In the example diagram of FIG. 1, certain components are shown located on an interface (IF) die 130, while other components are shown as part of each of a core dice 140. For the sake of clarity, only a single core die 140 and its components are shown; however, there may be multiple core dies (e.g., 2, 4, 6, 8, 16, or more) each with similar components to each other. The example semiconductor device 100 of FIG. 1 shows a particular arrangement of components between the IF die 130 and the core die 140; however, other arrangements may be used in other embodiments (e.g., a refresh control circuit 116 may be on the IF die 130 in some embodiments). For the sake of illustration, the core die 140 is drawn as a rectangular box which is smaller than the IF 130; however, the core die 140 and IF die 130 may have any size relationship to each other. For example, the core die 140 and IF die 130 may be approximately the same size.

The semiconductor device 100 includes a memory array 118 on each of the core dice 140. The memory array 118 is shown as including a plurality of memory banks. In the embodiment of FIG. 1, the memory array 118 is shown as including eight memory banks BANK0-BANK7. More or fewer banks may be included in the memory array 118 of other embodiments. Each memory bank includes a plurality of word lines WL, a plurality of bit lines BL, and a plurality of memory cells MC arranged at intersections of the plurality of word lines WL and the plurality of bit line BL. The selection of the word line WL is performed by a row decoder 108 and the selection of the bit lines BL is performed by a column decoder 110, each of which may also be located on each of the core dice. In the embodiment of FIG. 1, the row decoder 108 includes a respective row decoder for each memory bank and the column decoder 110 includes a respective column decoder for each memory bank. The bit lines BL are coupled to a respective sense amplifier (SAMP) of the memory array 118. Read data from the bit line BL is amplified by the sense amplifier SAMP, and transferred to read/write amplifiers (RWAMPs) 120 over complementary local data lines (LIOT/B), transfer gate (TG), and complementary main data lines (MIOT/B) which are coupled to RWAMP 120. Conversely, write data outputted from RWAMP 120 is transferred to the sense amplifier SAMP over the complementary main data lines MIOT/B, the transfer gate TG, and the complementary local data lines LIOT/B, and written in the memory cell MC coupled to the bit line BL.

The semiconductor device 100 may employ a plurality of external terminals located on the IF die 130 that include command and address (CA) terminals coupled to a command and address bus to receive commands and addresses, and a CS signal, clock terminals to receive clocks CK and/CK, data terminals DQ to provide data, and power supply terminals to receive power supply potentials VDD, VSS, VDDQ, and VSSQ.

The clock terminals on the IF die 130 are supplied with external clocks CK and/CK that are provided to an input circuit 112. The external clocks CK and/CK may be complementary. The input circuit 112 generates an internal clock ICLK based on the CK and/CK clocks. The ICLK clock is provided to the command decoder 106 and to an internal clock generator 114. The internal clock generator 114 provides various internal clocks LCLK based on the ICLK clock. The LCLK clocks may be used for timing operation of various internal circuits. The internal data clocks LCLK are provided to an input and output (IO) circuit 122 to time operation of circuits included in the IO circuit 122, for example, to data receivers to time the receipt of write data.

The internal clocks LCLK may include a read clock (RCLK) which is used to control the timing of read operations, and a write clock (WCLK) which is used to control the timing of write operations. The internal clocks may be passed to the IO circuit 122. In some instances, the internal clocks may also be passed to internal components of the core dice 140 such as RWAMP 120.

The CA terminals of the IF die 130 may be supplied with memory addresses. The memory addresses supplied to the CA terminals are transferred, via a command/address input circuit 102, to an address decoder 104. The address decoder 104 receives the address and supplies a decoded row address XADD to the row decoder 108 and supplies a decoded column address YADD to the column decoder 110. The address decoder 104 may also supply a decoded bank address BADD, which may indicate the bank of the memory array 118 containing the decoded row address XADD and column address YADD. The CA terminals may be supplied with commands. Examples of commands include timing commands for controlling the timing of various operations, access commands for accessing the memory, such as read commands for performing read operations and write commands for performing write operations, as well as other commands and operations. The access commands may be associated with one or more row address XADD, column address YADD, and bank address BADD to indicate the memory cell(s) to be accessed.

The commands may be provided as internal command signals to the command decoder 106 via the command/address input circuit 102 of the IF die 130. The command decoder 106 includes circuits to decode the internal command signals to generate various internal signals and commands for performing operations. For example, the command decoder 106 may provide a row command signal to select a word line and a column command signal to select a bit line.

The semiconductor device 100 may receive an access command which is a read command. When a read command is received, and a bank address, a row address and a column address are timely supplied with an activate command and the read command, read data is read from memory cells in the memory array 118 corresponding to the row address and column address. The read command is received by the command decoder 106, which provides internal commands so that read data from the memory array 118 is provided to RWAMP 120. The read data is output to outside the semiconductor device 100 from the data terminals DQ via the IO circuit 122.

The semiconductor device 100 may receive an access command which is a write command. When the write command is received, and a bank address, a row address and a column address are timely supplied with an activate command and the write command, and write data is supplied through the DQ terminals to RWAMP 120. The write data supplied to the data terminals DQ is written to a memory cells in the memory array 118 corresponding to the row address and column address. The write command is received by the command decoder 106, which provides internal commands so that the write data is received by data receivers in the IO circuit 122. Write clocks may also be provided to the external clock terminals for timing the receipt of the write data by the data receivers of the IO circuit 122. The write data is supplied via the IO circuit 122 to RWAMP 120.

The semiconductor device 100 may also receive commands causing it to carry out one or more refresh operations as part of a self-refresh mode. In some embodiments, the self-refresh mode command may be externally issued to the semiconductor device 100. In some embodiments, the self-refresh mode command may be periodically generated by a component of the device. In some embodiments, when an external signal indicates a self-refresh entry command, the refresh signal AREF may also be activated.

The power supply terminals of the IF die 130 are supplied with power supply potentials VDD and VSS. The power supply potentials VDD and VSS are supplied to an internal voltage generator circuit 124. The internal voltage generator circuit 124 generates various internal potentials such as VPP, VOD, VARY, VPERI, and the like based on the power supply potentials VDD and VSS supplied to the power supply terminals.

The power supply terminals of the IF die 130 are also supplied with power supply potential VDDQ. The power supply potential VDDQ is supplied to the IO circuit 122. The power supply potential VDDQ supplied to the power supply terminals may be the same potentials as the power supply potential VDD supplied to the power supply terminals in an embodiment of the disclosure. The power supply potential VDDQ supplied to the power supply terminals may be different potentials from the power supply potential VDD supplied to the power supply terminals in another embodiment of the disclosure. The power supply potential VDDQ supplied to the power supply terminals are used for the IO circuit 122 so that power supply noise generated by the IO circuit 122 does not propagate to the other circuit blocks.

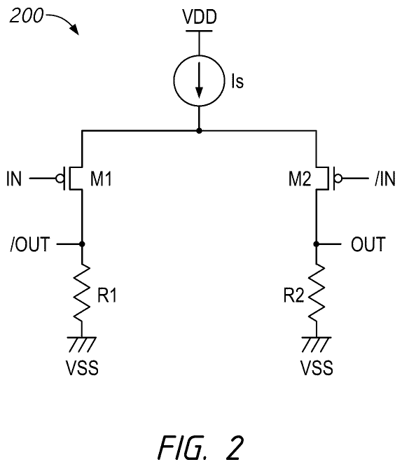

FIG. 2 is a circuit diagram of an example clock input buffer 200. The clock input buffer 200 may be included in or coupled to a semiconductor device, such as the semiconductor device 100. The clock input buffer 200 may be at least part of the clock input circuit 112 and/or the internal clock generator 114 of the semiconductor device 100. The clock input buffer 200 may be a differential amplifier. The term “coupled” herein may include “connected.”

The clock input buffer 200 includes p-channel metal-oxide-semiconductor (PMOS) transistors M1 and M2 and resistors R1 and R2. The PMOS transistor M1 and the resistor R1 are coupled in series. The PMOS transistor M2 and the resistor R2 are coupled in series. Sources of M1 and M2 are commonly coupled to a positive power supply VDD. Drains of M1 and M2 are coupled to terminals of R1 and R2 on one side, respectively. The drains of M1 and M2 and the terminals of R1 and R2 are commonly coupled to outputs /OUT and OUT, respectively. In some instances, the drains of M1 and M2 and the terminals of R1 and R2 are commonly coupled to output nodes to provide output clock signals /OUT and OUT, respectively. Terminals of R1 and R2 on another side are coupled to a negative power supply or ground VSS. Gates of M1 and M2 are coupled to inputs IN and /IN, respectively. In some instances, the gates of M1 and M2 are coupled to input nodes to receive input clock signals IN and /IN, respectively.

A voltage value of a common mode of the inputs IN and /IN may be significantly lower than a voltage value of the positive power supply VDD which is a supply source of constant current Is. For example, the voltage value of the common mode of IN and /IN may be 0.2V or around 0.2V or 0.4V or around 0.4V whereas the voltage value of VDD may be 1.05V or around 1.05V. The PMOS transistors coupled to such inputs and power supply function as input elements of the differential amplifier. The resistors R1 and R2 coupled to the outputs OUT and /OUT are loads of the differential amplifier. This differential amplifier may also be referred to as a resistor-load differential amplifier.

In the case of a memory device being a DDR DRAM (such as a LPDDR DRAM), for example, external clocks, such as differential clocks, may be provided to the inputs IN and /IN from a DDR data interface. In one instance, the external differential clocks are input to M1 and M2, respectively, and internal differential clocks output from the differential amplifier are used to latch external data input DQ. The differential clocks may be complementary. In some instances, the differential clocks may be differential forwarded clocks WCK and/WCK. WCK and/WCK may be complementary. In some embodiments, WCK and/WCK may be input to the terminals of the IF die 130 of the semiconductor device 100 as shown in FIG. 1.

In the resistor-load differential amplifier, however, desired or expected output amplitude may not be obtained at high frequency. For instance, when IN rises, that is IN turns high from low and /IN falls, that is /IN turns low from high, M1 resistance increases and M2 resistance decreases, respectively. Since the operation current Is provided by VDD is constant, M1 current decreases and M2 current increases, accordingly. This causes the level of /OUT coupled to M1 and R1 to decrease and the level of OUT coupled to M2 and R2 to increase. Similarly but conversely, when IN falls and /IN rises, /OUT increases and OUT decreases. At high frequency, such decrease of output amplitude occurs further extensively, possibly beyond a tolerable range. Therefore, in order to obtain output amplitude as desired or expected at high frequency, the operation current may need to be increased, which increases current consumption.

Some embodiments of the disclosure described in detail below address the above unintended, improper output amplitude at high frequency, without increasing current consumption.

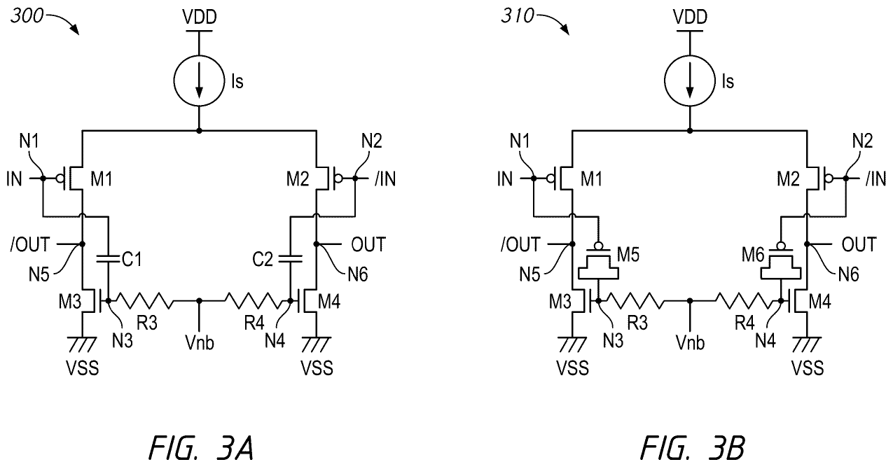

FIGS. 3A and 3B are circuit diagrams of example clock input buffers 300 and 310, respectively, according to an embodiment of the disclosure. In some embodiments, the clock input buffers 300 and/or 310 may be included in or coupled to a semiconductor device, such as the semiconductor device 100. In some embodiments, the clock input buffers 300 and/or 310 may be at least part of the clock input circuit 112 and/or the internal clock generator 114 of the semiconductor device 100. The clock input buffer 300 may be a differential amplifier. The term “coupled” herein may include “connected.”

With reference to FIG. 3A, the clock input buffer 300 includes n-channel metal-oxide-semiconductor (NMOS) transistors M3 and M4 as loads of the differential amplifier instead of the resistors R1 and R2 of the clock input buffer 200. The clock input buffer 300 further includes capacitors (or condensers) C1 and C2 and resistors R3 and R4 as shown in FIG. 3A. The PMOS transistors M1 and M2 remain as input elements of the differential amplifier. M1 and M2 may also be referred to as input PMOS transistors. The NMOS transistors M3 and M4 as loads of the differential amplifier. M3 and M4 may also be referred to as load NMOS transistors. This differential amplifier may also be referred to as a MOS-load differential amplifier. In some embodiments, the capacitors C1 and C2 may be replaced by PMOS transistors that function as capacitive devices (may also be referred to as capacitive elements). For example, with reference to FIG. 3B, the clock input buffer 310 includes NMOS transistors M3 and M4 as loads of the differential amplifier, and further includes resistors R3 and R4. Additionally, PMOS transistors M5 and M6 are configured as capacitors (or condensers) as shown in FIG. 3B. PMOS transistors M5 and M6 may be low threshold voltage (Vt) PMOS transistors. Vt may be, for example, −0.2V. In some embodiments, MOS transistors may be metal-insulator-silicon (MIS) transistors. The insulator may be a non-oxide insulator.

For both clock input buffers 300 and 310, the PMOS transistor M1 and the NMOS transistor M3 are coupled in series. A source of M1 is coupled to a positive power supply source VDD. A gate of M1 is coupled to an input node N1 to receive an input IN. The node N1 may also be referred to as a gate node of M1. In some instances, there may be a separate gate node of M1 coupled to the input node N1. A source of M3 is coupled to a negative power supply or ground VSS. Drains of M1 and M3 are coupled to each other. The drains of M1 and M3 are also commonly coupled to an output node N5 to provide an output /OUT.

Similarly for both clock input buffers 300 and 310, the PMOS transistor M2 and the NMOS transistor M4 are coupled in series. A source of M2 is coupled to the positive power supply source VDD. A gate of M2 is coupled to an input node N2 to receive an input /IN. The node N2 may also be referred to as a gate node of M2. In some instances, there may be a separate gate node of M2 coupled to the input node N2. A source of M4 is coupled to a negative power supply or ground VSS. Drains of M2 and M4 are coupled to each other. The drains of M2 and M4 are also commonly coupled to an output node N6 to provide an output OUT. In some embodiments, IN and /IN may be external differential clocks, and OUT and /OUT may be internal differential clocks.

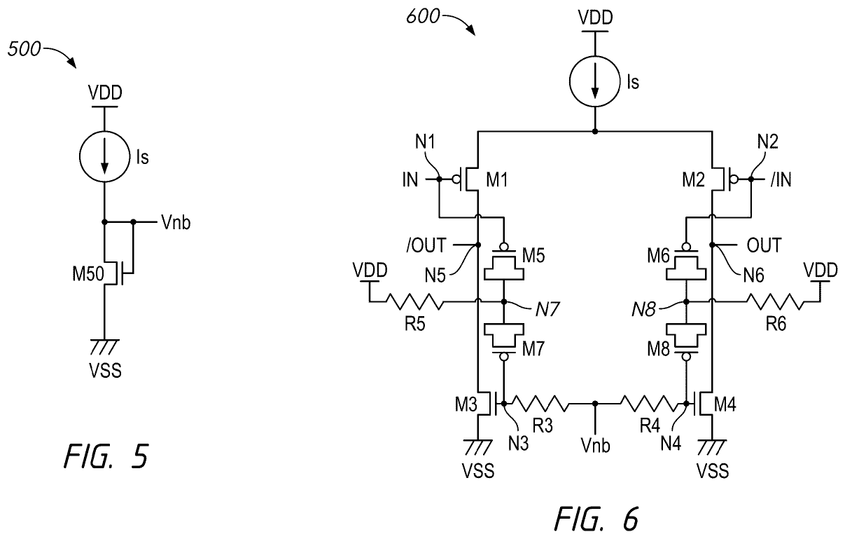

The capacitive devices, such as the capacitors C1 and C2 (FIG. 3A) and the PMOS transistors M5 and M6 (FIG. 3B), are coupled to the input nodes N1 and N2 and gates or gate nodes N3 and N4 of M3 and M4. In some instances where there are a gate node of M1 coupled to the input node N1 and a gate node of M2 coupled to the input node N2, terminals of the capacitive devices on one side may be coupled to such gate nodes of M1 and M2, respectively, whereas terminals of the capacitive devices on another side are coupled to N3 and N4 of M3 and M4, respectively. The gate nodes N3 and N4 of M3 and M4 are coupled to a bias voltage Vnb through R3 and R4, respectively. R3 and R4 are coupled in series between M3 and M4. Vnb may be generated by, for example, a bias voltage generator 500 according to an embodiment of the disclosure as shown in FIG. 5. The bias voltage generator 500 includes at least one diode-connected NMOS transistor M50 coupled to VDD and VSS to generate the bias voltage Vnb. Vnb may be, for example, 0.5V.

In some instances, the clock input buffers 300 and 310 operate at higher frequencies than the clock input buffer 200. As compared with the clock input buffer 200, the resistors R1 and R2 which are the loads of the differential amplifier of the clock input buffer 200 are replaced by the NMOS transistors M3 and M4 which are the loads of the differential amplifier of the clock input buffer 300 and the clock input buffer 310. M3 and M4 may also be referred to as NMOS loads or simply MOS loads. The gate nodes N3 and N4 of the MOS loads M3 and M4 are coupled to the bias voltage Vnb through the series-coupled resistors R3 and R4, respectively. The inputs IN and /IN are coupled to N3 and N4 of M3 and M4 by the capacitive devices, for example the capacitors C1 and C2 for the clock input buffer 300 or the PMOS transistors M5 and M6 for the clock input buffer 310, respectively.

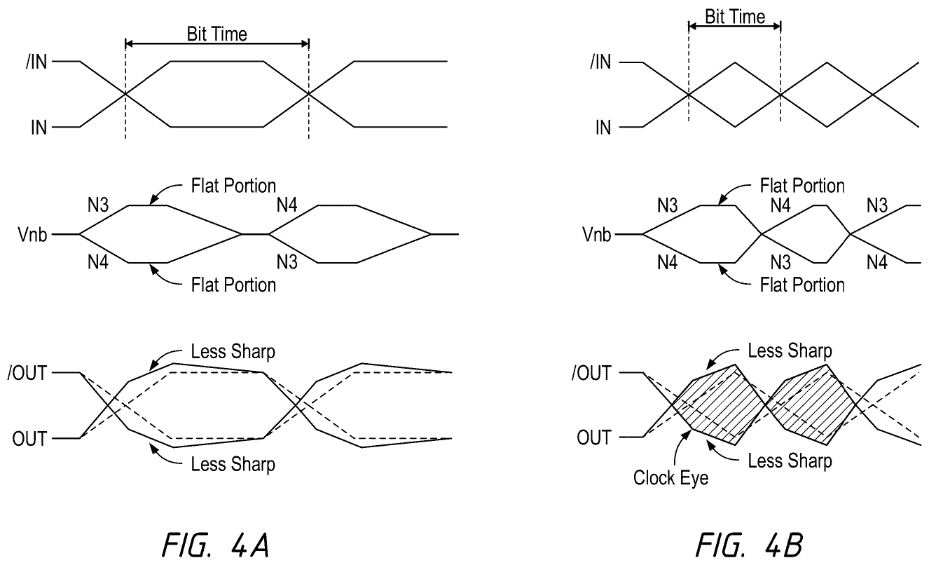

FIGS. 4A and 4B illustrate example waveforms at a lower operating frequency and at a higher operating frequency, respectively, according to an embodiment of the disclosure. The solid lines are the waveforms of the clock input buffer 300 and clock input buffer 310. The dashed lines are the waveforms of the clock input buffer 200. The lower operating frequency may be, for example, 1.6 GHz. The higher operating frequency may be, for example, 4.8 GHz.

At both the lower operating frequency (where the bit time is longer) and the higher operating frequency (where the bit time is shorter) as illustrated in FIGS. 4A and 4B, when IN rises, that is IN turns high (e.g., 0.4V) from low (e.g., 0.0V), the resistance of M1 increases and the current flowing at M1 decreases. As a result, the IR drop across M3 decreases, and hence, /OUT falls. At the same time, the voltage level of the gate node N3 of M3 rises from the static level Vnb due to the coupling by C1 (FIG. 3A) or M5 (FIG. 3B) and the resistance of M3 decreases. As a result, the IR drop across M3 further decreases, and hence, /OUT further falls. Accordingly, because of the effect of the increase of M1 resistance due to the IN rise and the effect of the decrease of M3 resistance due to the rise of N1 voltage level caused by the capacitive coupling, the fall of the /OUT level is further accelerated. Consequently, /OUT (illustrated with the solid lines) falls sharper and the output amplitude of the clock input buffer 300 and the clock input buffer 310 becomes greater than those (illustrated with the dotted lines) of the clock input buffer 200.

Likewise, when /IN falls, that is /IN turns low (e.g., 0.0V) from high (e.g., 0.4V), the resistance of M2 decreases and the current flowing at M2 increases. As a result, the IR drop across M4 increase, and hence, OUT rises. At the same time, the voltage level of the gate node N4 of M4 falls from Vnb due to the coupling by C2 (FIG. 3A) or M6 (FIG. 3B) and the resistance of M4 increases. As a result, the IR drop across M4 further increases, and hence, OUT further rises. Accordingly, because of the effect of the decrease of M2 resistance due to the /IN fall and the effect of the increase of M4 resistance due to the fall of N4 voltage level caused by the capacitive coupling, the rise of the OUT level is further accelerated. Consequently, OUT (illustrated with the solid lines) rises sharper and the output amplitude of the clock input buffer 300 and the clock input buffer 310 becomes greater than those (illustrated with the dotted lines) of the clock input buffer 200.

Furthermore, in some embodiments, the resistors R3 and R4 may be configured such that the time constant obtained by multiplying resistance values of R3 and R4 with capacitance values at the nodes N3 and N4, respectively, is a quarter (or approximately a quarter) or a half (or approximately a half) of the bit time at the higher operating frequency (FIG. 4B). With such resistor design, while the input is transitioning from low to high or high to low, the slope of each of N3 and N4 voltage level becomes flat or flatter at a certain time rather than continually rising, and the corresponding slope of each of /OUT and OUT becomes less sharp. This avoids excessive overshoot of both the nodes and the outputs at the end of the input transition. Especially at a higher operating frequency, this suppresses or mitigates interference to the next input transition, while achieving the size of the clock “eye” of the clock input buffer 300 substantively greater than that of the clock input buffer 200. Thus, the faster transition and the avoidance of greater overshoot enable the faster operating frequency of the clock input buffer 300 than the clock input buffer 200.

Moreover, at both the lower operating frequency and the higher operating frequency, the VDD power of the clock input buffer 300 is not increased from that of the clock input buffer 200, and hence the current consumption does not increase.

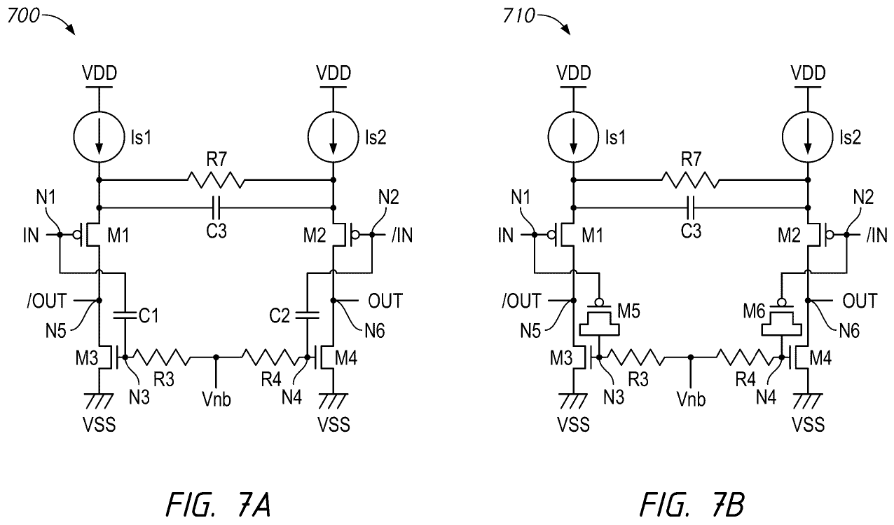

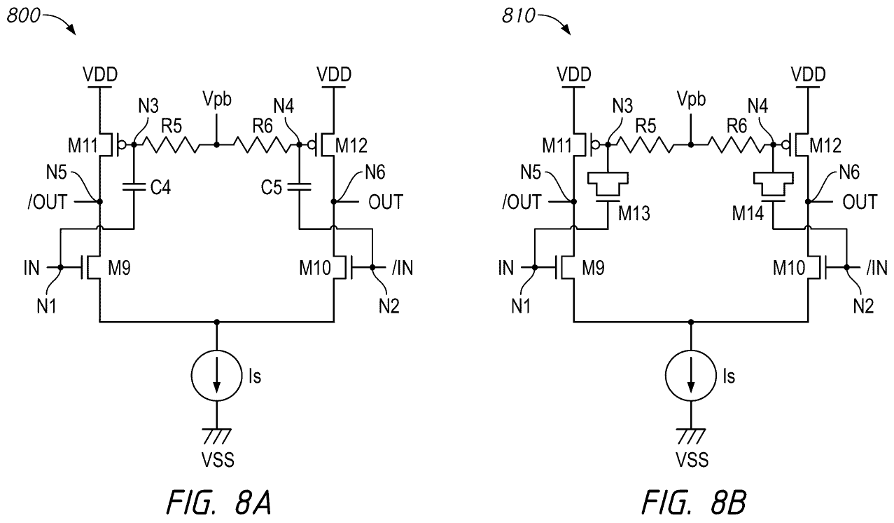

FIG. 6 is a circuit diagram of an example clock input buffer 600 according to an embodiment of the disclosure. In FIG. 6, the coupling capacitive devices are realized by a pair of PMOS transistors M5 and M7 and another pair of PMOS transistors M6 and M8. The PMOS transistors M5-M8 may be low Vt PMOS transistors. In the pair of M5 and M7, sources and drains are coupled to each other at a mid-node N7. The gate of M5 is coupled to the node N1. The gate of M7 is coupled to the node N3 of M3 and R3. In the pair of M6 and M8, sources and drains are coupled to each other at a mid-node N8. The gate of M6 is coupled to the node N2. The gate of M8 is coupled to the node N4 of M4 and R4. The clock input buffer 600 further includes resistors R5 and R6 coupled to the mid-nodes N7 and N8, respectively. The sources and drains of M5 and M7 are commonly coupled to the power supply VDD through the mid-node N7 and the resistor R5. The sources and drains of M6 and M8 are commonly coupled to the power supply VDD through the mid-node N8 and the resistor R6. The mid-nodes N7 and N8 are biased at the power supply VDD through the resistors R5 and R6, respectively. The resistor R5 is provided to cause N3, M5, and M7 to be high when IN is high. The resistor R6 is provided to cause N4, M6, and M8 to be high when /IN is high.

The circuit configuration of the clock input buffer 600 may be more advantageously used than the clock input buffer 300 in a case where the bias voltage Vnb is lower than the expected design voltage of, for example, 0.5V. It may also be more advantageous in a case where the threshold voltage Vt of each of the PMOS transistors is higher than, for example, |−0.2V|. One non-limiting example case may be where a PMOS transistor of low Vt, such as −0.2V, may not be available due to process designs and a PMOS transistor of high Vt, such as |−0.4V|, is used instead. Furthermore, the clock input buffer 600 may be more advantageous than the clock input buffer 300 if M5 and M6 directly coupled to the gate nodes N3 and N4 as in the clock input buffer 300 are not in a strong inversion region (where Vgs>Vt) in operation.

FIGS. 7A and 7B are circuit diagrams of example clock input buffers 700 and 710, respectively, according to an embodiment of the disclosure. The clock input buffer 700 may be the same or substantially the same as the clock input buffer 300, except that the clock input buffer 700 is applied to a continuous-time linear equalizer (CTLE) amplifier. The clock input buffer 710 may be the same or substantially the same as the clock input buffer 310, except that the clock input buffer 710 is applied to a continuous-time linear equalizer (CTLE) amplifier. In the clock input buffer 200, 300, 310, and 600, VDD is shared between the input transistors M1 and M2. In the clock input buffers 700 and 710 each as the CTLE amplifier, two power supplies VDD are used to provide constant currents Is1 and Is2 to the input transistors M1 and M2, respectively. Is1 and Is2 may have the same current value. The clock input buffers 700 and 710 further include a resistor R7 and a capacitor C3 coupled in parallel between the two voltage/current routes. In the CTLE amplifier, a source of each of the input transistors M1 and M2 may be degenerated by the resistor R7 and the capacitor C3 with the current sources Is1 and Is2. During the source degeneration, the current path may be separated or coupled at the resistor and the capacitor.

As described above, the clock input buffers 300, 310, 600, 700, and 710 may operate at high frequency without increasing current consumption compared to the clock input buffer 200.

FIGS. 8A and 8B are circuit diagrams of example clock input buffers 800 and 810, respectively, according to an embodiment of the disclosure. In some embodiments, the clock input buffer 800 may be included in or coupled to a semiconductor device, such as the semiconductor device 100. In some embodiments, the clock input buffer 800 may be at least part of the clock input circuit 112 and/or the internal clock generator 114 of the semiconductor device 100. The clock input buffer 800 may be a differential amplifier. In some embodiments, the clock input buffer 810 may be included in or coupled to a semiconductor device, such as the semiconductor device 100. In some embodiments, the clock input buffer 810 may be at least part of the clock input circuit 112 and/or the internal clock generator 114 of the semiconductor device 100. The clock input buffer 810 may be a differential amplifier. The term “coupled” herein may include “connected.”

The clock input buffers 800 and 810 have circuit configurations with the VDD side and the VSS side relative to the circuit configuration of the clock input buffers 300 and 310. The clock input buffers 800 and 810 include NMOS transistors M9 and M10 as input transistors with gates thereof respectively coupled to the inputs IN and /IN and sources thereof commonly coupled to the negative power supply or ground VSS. The clock input buffers 800 and 810 include PMOS transistors M11 and M12 as load transistors (or MOS loads) with sources thereof coupled to the respective positive power supplies VDD and gates thereof commonly coupled to a bias positive voltage Vpb (unlike the bias negative voltage Vnb in the clock input buffers 300 and 310) through the respective resistors R5 and R6. The value of VDD may be, for example, 1.1V or around 1.1V. Vpb may be, for example, 0.6V or around 0.6V. A voltage value of a common mode of the inputs IN and /IN may be 0.8V or around 0.8V. In some embodiments, the input clock signals to IN and /IN may be, for example, data strobe signals DQS and/DQS that are complementary and are used as clocks to capture input data for a write operation of a DRAM, such as a DDR DRAM.

The NMOS transistor M9 and the PMOS transistor M11 are coupled in series with drains thereof coupled to each other. The drains of M9 and M11 are also commonly coupled to the output node N5 to provide the output /OUT. The NMOS transistor M10 and the PMOS transistor M12 are coupled in series with drains thereof coupled to each other. The drains of M10 and M12 are also commonly coupled to the output node N6 to provide the output OUT.

Similarly to the clock input buffers 300 and 310, the clock input buffers 800 and 810 include capacitive devices. For example, the clock input buffer 800 includes capacitors C4 and C5 (FIG. 8A), and the clock input buffer 810 includes NMOS transistors M13 and M14 (FIG. 8B). The NMOS transistors M13 and M14 may be low Vt NMOS transistors. Vt may be, for example, 0.2V. The capacitive devices are coupled to the input nodes N1 and N2 (which may also be the gate nodes of M9 and M10) on one side and the coupling nodes N3 and N4 (which may also be the gate nodes of M11 and M12) on another side. The nodes N3 and N4 are coupled to Vpb through R3 and R4, respectively. Vpb may be generated by a similar generator to the bias voltage generator 500 of FIG. 5. In some embodiments, M13 and M14 may include a pair of NMOS transistors and another pair of NMOS transistors, respectively, in a similar manner to the pair of M5 and M7 and the pair of M6 and M8 of the clock input buffer 600.

With this circuit configuration, similarly to the clock input buffers 300, 310, 600, 700, and 710, the clock input buffers 800 and 810 may operate at a high frequency without increasing current consumption compared to the clock input buffer 200.

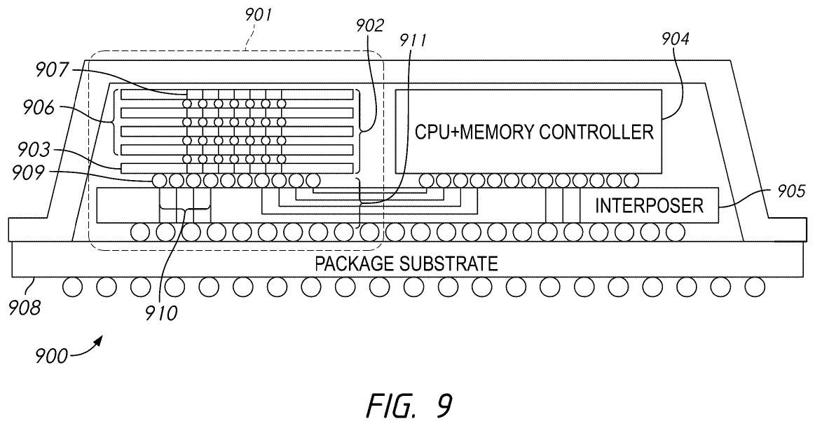

FIG. 9 depicts a schematic configuration of an example semiconductor system 900 according to an embodiment of the disclosure. The semiconductor system 900 includes a semiconductor memory device 901 in an embodiment of the disclosure. In some embodiments of the disclosure, the semiconductor memory device 901 may include the semiconductor device 100 of FIG. 1. The semiconductor system 900 may also include a central processing unit (CPU) and memory controller 904, which may be a controller chip, on an interposer 905 on a package substrate 908. The interposer 905 may include one or more power lines 910 which may supply power supply voltage from the package substrate 908. The interposer 905 may include a plurality of channels 911 that may interconnect the CPU and memory controller 904 and the semiconductor memory device 901. The semiconductor memory device 901 may be a DRAM. The DRAM may be a DDR DRAM. The memory controller 904 may provide a clock signal, a command signal, and may further transmit and receive data signals. The plurality of channels 911 may transmit the data signals between the memory controller and the memory device 901.

The semiconductor memory device 901 may include a plurality of dies (or chips) 902 including at least one interface (IF) die (or chip) 903 and a plurality of memory core dies (or chips) 906 stacked with each other. In some embodiments, each of the plurality of memory core dies 906 may include the core die 140 and the IF die 903 may include the IF die 130 of the semiconductor device 100. In some embodiments, the clock input buffers 300, 310, 600, 700, 710, 800, and 810 may be implemented in the IF die 903.

A number of the memory core dies 906 may not be limited to four as in the illustrated example, and may be more or fewer as appropriate. Each of the memory core dies 906 may include a plurality of memory cells and circuitries accessing the memory cells. For example, the memory cells may be DRAM cells. The memory cells may be arranged in array. The semiconductor memory device 901 may include conductive vias 907 which couple the IF die 903 and the memory core dies 906 by penetrating the IF die 903 and the memory core dies 906. The IF die 903 may be coupled to the interposer 905 via interconnects 909. For example, the interconnects 909 may be microbumps having bump pitches of less than about or less than one hundred micrometers and exposed on an outside of the IF die 903. A portion of each of the interconnects 909 may be coupled to the one or more power lines 910. Another portion of each of the interconnects 909 may be coupled to one or more of the channels 911.

DRAM is merely one example, and the embodiments and the descriptions herein are not intended to be limited to DRAM. Memory devices other than DRAM, such as a static random-access memory (SRAM), a flash memory, an erasable programmable read-only memory (EPROM), a magnetoresistive random-access memory (MRAM), and a phase-change memory, can also be applied as the semiconductor memory device 901. Furthermore, devices other than memory, including logic ICs, such as a microprocessor and an application-specific integrated circuit (ASIC), are also applicable as the semiconductor device according to the present embodiments.

Although various embodiments of the disclosure have been described in detail, it will be understood by those skilled in the art that embodiments of the disclosure may extend beyond the specifically described embodiments to other alternative embodiments and/or uses and modifications and equivalents thereof. In addition, other modifications which are within the scope of the disclosure will be readily apparent to those of skill in the art based on the described embodiments. It is also contemplated that various combination or sub-combination of the specific features and aspects of the embodiments may be made and still fall within the scope of the disclosure. It should be understood that various features and aspects of the embodiments can be combined with or substituted for one another in order to form varying mode of the embodiments. Thus, it is intended that the scope of the disclosure should not be limited by the particular embodiments described above.

What is claimed is:

1. An apparatus, comprising:
first and second input transistors of a first type, gate nodes of the first and second input transistors coupled to first and second inputs, respectively;
first and second load transistors of a second type coupled to the first and second input transistors in series, respectively, the first input transistor and first load transistor coupled to a first output, the second input transistor and second load transistor coupled to a second output;
at least one resistor coupled to gate nodes of the first and second load transistors, the gate nodes of the first and second load transistors coupled to a bias voltage through the at least one resistor;
a first capacitive device coupled to the first input and to the gate node of the first load transistor; and
a second capacitive device coupled to the second input and to the gate node of the second load transistor.

2. The apparatus according to claim 1, wherein the first and second capacitive devices comprise capacitors.

3. The apparatus according to claim 1, wherein the first and second capacitive devices comprise MIS transistors.

4. The apparatus according to claim 1, wherein the first and second capacitive devices comprise low threshold voltage MOS transistors.

5. The apparatus according to claim 1, wherein
the first capacitive device is coupled to the gate node of the first input transistor and to the gate node of the first load transistor, and
the second capacitive device is coupled to the gate node of the second input transistor and to the gate node of the second load transistor.

6. The apparatus according to claim 1, wherein the at least one resistor comprises a plurality of resistors coupled in series between the gate nodes of the first and second load transistors.

7. The apparatus according to claim 6, wherein a common node of the series-coupled resistors is coupled to the bias voltage.

8. The apparatus according to claim 1, wherein the input transistors of the first type comprise PMOS transistors, and the load transistors of the second type comprise NMOS transistors.

9. The apparatus according to claim 1, wherein the first capacitive device comprises a first pair of MOS transistors between the first input of the apparatus and the gate node of the first load transistor, and the second capacitive device comprises a second pair of MOS transistors between the second input of the apparatus and the gate node of the second load transistor.

10. The apparatus according to claim 1, wherein the apparatus includes a clock input buffer, the clock input buffer including the first and second input transistors, the first and second load transistors, the at least one resistor, and the first and second capacitive devices and configured to receive external clock signals at the first and second inputs and output internal clock signals at the first and second outputs.

11. The apparatus according to claim 10, wherein the clock input buffer is a differential amplifier.

12. The apparatus according to claim 1, further comprising a bias voltage generator configured to generate the bias voltage.

13. A clock input buffer, comprising:
first and second input transistors of a first type, gate nodes of the first and second input transistors coupled to first and second inputs of the clock input buffer, respectively; and
first and second load transistors of a second type coupled to the first and second input transistors in series, respectively, the first input transistor and first load transistor coupled to a first output of the clock input buffer, the second input transistor and second load transistor coupled to a second output of the clock input buffer,
wherein gate nodes of the first and second load transistors are coupled to a bias voltage through at least one resistor, and
wherein the first and second inputs are coupled to the gate nodes of the first and second load transistors through first and second capacitors, respectively.

14. The clock input buffer according to claim 13, wherein the first capacitor is coupled to the gate nodes of the first input transistor and first load transistor, and the second capacitor is coupled to the gate nodes of the second input transistor and second load transistor.

15. The clock input buffer according to claim 13, configured to receive complementary clock signals at the first and second inputs.

16. A clock input buffer, comprising:
first and second input transistors of a first type, gate nodes of the first and second input transistors coupled to first and second inputs of the clock input buffer, respectively; and
first and second load transistors of a second type coupled to the first and second input transistors in series, respectively, the first input transistor and first load transistor coupled to a first output of the clock input buffer, the second input transistor and second load transistor coupled to a second output of the clock input buffer,
wherein gate nodes of the first and second load transistors are coupled to a bias voltage through at least one resistor, and
wherein the first and second inputs are coupled to the gate nodes of the first and second load transistors through third and fourth transistors of the first type, respectively.

17. The clock input buffer according to claim 16, wherein the input transistors of the first type comprise PMOS transistors, the load transistors of the second type comprise NMOS transistors, and the third and fourth transistors of the first type comprise PMOS transistors.

18. The clock input buffer according to claim 16, wherein the third transistor of the first type comprises a first pair of PMOS transistors between the first input of the clock input buffer and the gate node of the first load transistor, and the fourth transistor of the first type comprises a second pair of PMOS transistors between the second input of the clock input buffer and the gate node of the second load transistor.

19. The clock input buffer according to claim 16, wherein the first and second inputs are configured to receive complementary clock signals at the first and second inputs.

20. The clock input buffer according to claim 16, wherein the input transistors of the first type comprise NMOS transistors, the load transistors of the second type comprise PMOS transistors, and the third and fourth transistors of the first type comprise NMOS transistors.
